(19) United States
(12) Patent Application Publication
(10) Pub. No.: US 2025/0369154 A1
(43) Pub. Date: Dec. 4, 2025

(54) MATERIAL DEPOSITION APPARATUS AND RELATED METHOD

(71) Applicant: ASM IP Holding B.V., Almere (NL)

(72) Inventors: Niels Claessens, Heverlee (BE); Brendan Marozas, Leuven (BE)

(21) Appl. No.: 19/219,468

(22) Filed: May 27, 2025

Related U.S. Application Data
(60) Provisional application No. 63/653,322, filed on May 30, 2024.

(51) Int. Cl. C30B 25/18; C30B 25/08; C30B 25/12; C30B 25/16; C30B 33/08

(52) U.S. Cl. CPC C30B 25/18; C30B 25/08; C30B 25/12; C30B 25/16; C30B 33/08

(57) ABSTRACT

Material deposition apparatuses and related methods described. Presently described apparatuses and methods allow executing cyclical deposition-etch processes with varying substrate rotation speeds during deposition and etch steps. Thus, they allow depositing a material with excellent uniformity.

### CROSS-REFERENCE TO RELATED APPLICATION(S)

This Application claims the benefit of U.S. Provisional Application 63/653,322 filed on May 30, 2024, the entire contents of which are incorporated herein by reference.

### FIELD OF INVENTION

The presently disclosed subject matter is in the field of material deposition systems and related methods which can be employed, for example, for integrated circuit manufacturing.

### BACKGROUND OF THE DISCLOSURE

With advancing complementary metal oxide semiconductor (CMOS) technology, lower epitaxial deposition temperature is becoming more critical. In particular, epitaxial processes at temperatures less than 500° C. are required to enable various novel integration schemes, e.g., stacking devices, buried power rail, high k/metal gate first integrations, and source/drain contact layer formation. As deposition temperatures decrease, achieving within-wafer uniform doping in epitaxial phosphorus-doped silicon becomes challenging, leading to poor overall uniformity of the deposited material. Performing the epitaxial growth at different process conditions such as lower pressures or higher carrier flows can increase uniformity of incorporated phosphorus. However, this often causes a decrease in selectivity of the process towards dielectrics which is essential for the selective growth of the epi-material within devices.

Thus, there remains a need for improved deposition processes and systems.

### SUMMARY OF THE DISCLOSURE

Described herein is a material deposition apparatus comprising a reaction chamber comprising a substrate support; the substrate support being constructed and arranged for supporting a substrate; a substrate moving robot, the substrate moving robot being constructed and arranged for positioning the substrate on the substrate support; a rotary actuator that is constructed and arranged for rotating the substrate support; a precursor line which is constructed and arranged for fluidly connecting a precursor source comprising a precursor to the reaction chamber; a precursor valve which is constructed and arranged for opening and closing the precursor line; an etchant line which is constructed and arranged for fluidly connecting an etchant source comprising an etchant to the reaction chamber; an etchant valve which is constructed and arranged for opening and closing the etchant line; a sequence controller which is constructed and arranged for causing the material deposition apparatus to execute a cyclical deposition process, the cyclical deposition process comprising executing a plurality of cycles, ones from the plurality of cycles comprising a deposition step and an etching step, wherein the deposition step comprises providing precursor via the precursor line to the reaction chamber to expose the substrate to the precursor while rotating the substrate support at a deposition angular frequency by means of the rotary actuator; wherein the etching step comprises providing etchant via the etchant line to the reaction chamber to expose the substrate to the etchant while rotating the substrate support at an etching angular frequency by means of the rotary actuator, the etching angular frequency being different from the deposition angular frequency, to selectively form a layer on the first surface vis-à-vis the second surface.

In some embodiments, the layer is epitaxially formed on the first surface.

In some embodiments, the first surface comprises s a monocrystalline semiconductor.

In some embodiments, the monocrystalline semiconductor comprises silicon.

In some embodiments, the second surface comprises a dielectric.

In some embodiments, the dielectric comprises one or more of silicon oxide and silicon nitride.

In some embodiments, the precursor comprises a silicon precursor.

In some embodiments, the silicon precursor has a general formula of the form SiₙH₂ₙ₋₂₋ₘXₘ, with X being selected from Cl, Br, and I, with n being an integer from at least 1 to at most 6, and with m being an integer from at least 0 to at most 2n-2.

In some embodiments, the silicon precursor comprises disilane.

In some embodiments, the material deposition apparatus further comprises a dopant precursor line which is constructed and arranged for fluidly connecting a dopant precursor source comprising a dopant precursor to the reaction chamber; and, a dopant precursor valve which is constructed and arranged for opening and closing the dopant precursor line; wherein the deposition step further comprises providing the dopant precursor via the dopant precursor line to the reaction chamber to expose the substrate to the dopant precursor.

In some embodiments, providing the dopant precursor to the reaction chamber and providing the precursor to the reaction chamber occur simultaneously.

In some embodiments, the dopant precursor comprises a phosphorous precursor.

In some embodiments, the phosphorous precursor comprises phosphine.

In some embodiments, the rotary actuator includes at least one of a stepper motor and a servo motor.

Further described herein is a method of forming a layer on a substrate, the substrate comprising a first surface and a second surface, wherein the method comprises positioning the substrate on a substrate support; and, a cyclical deposition process, wherein the cyclical deposition process comprises executing a plurality of cycles, ones from the plurality of cycles comprising a deposition step and an etching step, wherein the deposition step comprises exposing the substrate to a precursor while rotating the substrate at a deposition angular frequency by means of the substrate support; wherein the etching step comprises exposing the substrate to an etchant while rotating the substrate at an etching angular frequency by means of the substrate support, the etching angular frequency being different from the rotation angular frequency; thereby selectively forming the layer on the first surface vis-à-vis the second surface.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

FIG. 1 illustrates an embodiment of a material deposition apparatus 100.

FIG. 2 illustrates an embodiment of a cyclical deposition process 200.

FIG. 3 illustrates an embodiment of a method 300 of forming a layer.

FIG. 4 illustrates an embodiment of a substrate 130.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below

As used herein, the term “substrate” may refer to any underlying material or materials, including any underlying material or materials that may be modified, or upon which, a device, a circuit, or a film may be formed. The “substrate” may be rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

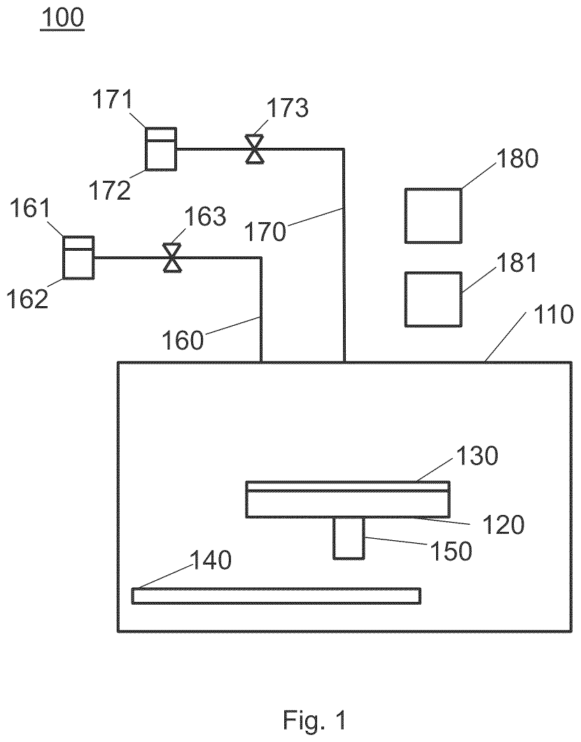

Referring to FIG. 1, described herein is an embodiment of a material deposition apparatus 100. The material deposition apparatus 100 comprises a reaction chamber 110. The reaction chamber 110 comprises a substrate support 120. The substrate support 120 is constructed and arranged for supporting a substrate 130. The material deposition apparatus 100 further comprises a substrate moving robot 140. The substrate moving robot 140 is constructed and arranged for positioning the substrate 130 on the substrate support 120. The material deposition apparatus 100 further comprises a rotary actuator 150. Suitable rotary actuators 150 are known in the art and may include stepper motors and servo motors. The rotary actuator 150 is constructed and arranged for rotating the substrate support 120. The material deposition apparatus 100 further comprises a precursor line 160. The precursor line 160 is constructed and arranged for fluidly connecting a precursor source 161 that comprises a precursor 162 to the reaction chamber 110. The material deposition apparatus 100 further comprises a precursor valve 163. The precursor valve 163 is constructed and arranged for opening and closing the precursor line 160. The material deposition apparatus 100 further comprises an etchant line 170. The etchant line 170 is constructed and arranged for fluidly connecting an etchant source 171 that comprises an etchant 172 to the reaction chamber 110. The material deposition apparatus 100 further comprises an etchant valve 173. The etchant valve 173 is constructed and arranged for opening and closing the etchant line 170. The material deposition apparatus 100 further comprises a sequence controller 180. The sequence controller 180 is constructed and arranged for causing the material deposition apparatus 100 to execute a cyclical deposition process.

In some embodiments, the material deposition apparatus 100 can comprise a temperature controller 101. The sequence controller 180 can be constructed and arranged for causing the temperature controller to heat the substrate to a temperature of at least 200° C. to at most 500° C., for example to a temperature of at least 200° C. to at most 300° C., or to a temperature of at least 300° C. to at most 400° C., or to a temperature of at least 400°0 C. to at most 500° C. Suitable temperature controllers 101 can comprise one or more heating elements such as infrared lamps and one or more temperature sensors such as thermocouples and pyrometers.

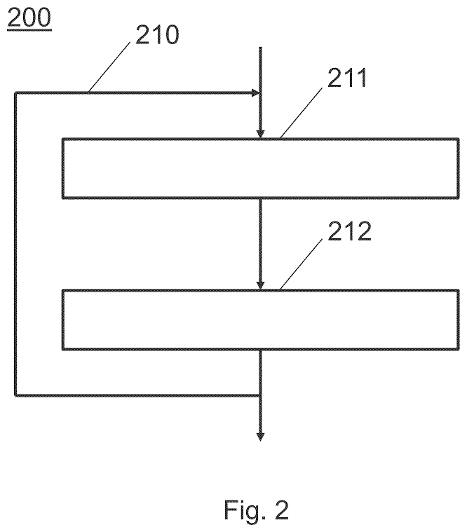

An embodiment of a cyclical deposition process 200 is described with reference to FIG. 2. The cyclical deposition process 200 comprises executing a plurality of cycles 210, for example from at least 1 to at most 100 cycles, or at least 1 to at most 5 cycles, or at least 5 to at most 10 cycles, or at least 10 to at most 20 cycles, or at least 20 to at most 50 cycles, or at least 50 to at most 100 cycles, or at least 1o to at most 30 cycles. In some embodiments, the cyclical deposition process 200 comprises 20 cycles. Ones from the plurality of cycles 210 comprise a deposition step 211 and an etching step 212. The deposition step 211 comprises providing the precursor 162 via the precursor line 160 to the reaction chamber 110 to expose the substrate 130 to the precursor 162 while rotating the substrate support 120 at a deposition angular frequency by means of the rotary actuator 150. The etching step 212 comprises providing the etchant 172 via the etchant line 170 to the reaction chamber 110 to expose the substrate 130 to the etchant 172. While the substrate 130 is exposed to the etchant 172, the substrate support 120 is rotated at an etching angular frequency by means of the rotary actuator 150. It shall be understood that the etching angular frequency and the deposition angular frequency are different.

In some embodiments, the etching angular frequency is greater than the deposition angular frequency, e.g. from at least 1% to at most 5% greater, or from at least 5% to at most 10% greater, or from at least 10% to at most 20% greater, or from at least 20% to at most 50% greater, or from at most 50% to at most 100% greater, or from at least 100% to at most 200% greater, or from at least 200% to at most 500% greater, or from at least 500% to at most 1000% greater.

In some embodiments, the deposition angular frequency is greater than the etching angular frequency, e.g. from at least 1% to at most 5% greater, or from at least 5% to at most 10% greater, or from at least 10% to at most 20% greater, or from at least 20% to at most 50% greater, or from at most 50% to at most 100% greater, or from at least 100% to at most 200% greater, or from at least 200% to at most 500% greater, or from at least 500% to at most 1000% greater.

In some embodiments, at least one of the etching angular frequency and the deposition angular frequency is from at least 0.1 rad/s to at most 100 rad/s, or from at least 0.1rad/s to at most 1.0 rad/s, or from at least 1.0 rad/s to at most 10 rad/s, or from at least 10 rad/s to at most 100 rad/s. In some embodiments, at least one of the etching angular frequency and the deposition angular frequency is from at least 0 rad/s to at most 11 rad/s, or from at least 1.25 rad/s to at most 8.0 rad/s.

By employing different rotation speeds, i.e. angular frequencies, of the susceptor during deposition and etch, uniformity of deposition and etching can be separately optimized. This, in turn, can yield an improved overall process uniformity.

The expression “deposition rotation rate” as used herein can be used interchangeably with like expressions such as “first rotation rate” and the like.

The expression “etching rotation rate” as used herein can be used interchangeably with like expressions such as “second rotation rate” and the like.

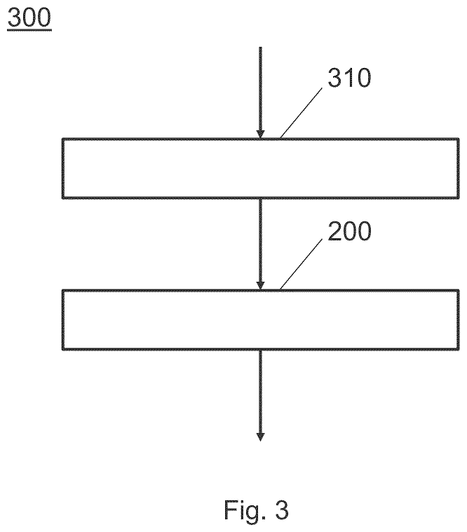

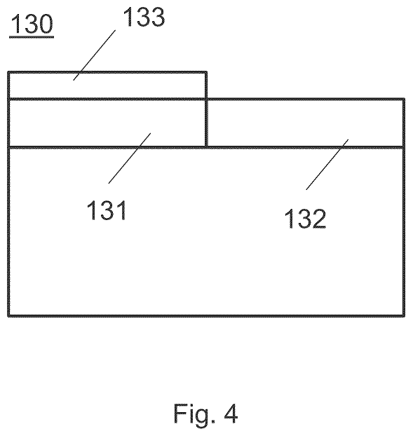

Referring to FIGS. 3 and 4, further described herein is an embodiment of a method 300 of forming a layer 133 on a substrate 130. The substrate 130 comprises a first surface 131 and a second surface 132. The method 300 comprises positioning 310 the substrate 130 on a substrate support 120. The method 300 further comprises executing a cyclical deposition process 200 as described herein. Thus, the layer 133 can be selectively formed on the first surface 131 vis-à-vis the second surface 132.

A cyclical deposition process as described herein comprises a plurality of deposition steps and etching steps. During each deposition step, more material is grown on a first surface than on a second surface, for example through nucleation delay, though selectivity may not be perfect, and some material may grow on the second surface as well during any one deposition step. By cyclically etching such parasitic material growth on the second surface, an overall process with perfect or near-perfect selectivity may be achieved.

In some embodiments, the layer is epitaxially formed on the first surface.

In some embodiments, the precursor comprises a silicon precursor. In some embodiments, the silicon precursor is selected from a silane and a halosilane, such as SiH₄, SiCl₄, SiCl₃H, SiCl₂H₂, and SiClH₃. In some embodiments, the silicon precursor comprises disilane. In some embodiments, the silicon precursor comprises trisilane. In some embodiments, the silicon precursor has a general formula of the form SiₙH₂ₙ₋₂₋ₘXₘ, with X being selected from Cl, Br, and I, with n being an integer from at least 1 to at most 6, and with m being an integer from at least 0 to at most 2n-2. For example, the precursor can be provided to the reaction chamber at a flow rate of at least 50 sccm to at most 700 sccm, or from at least 100 sccm to at most 600 sccm.

In some embodiments, a material deposition apparatus as described herein further comprises a dopant precursor line which is fluidly connectable to a dopant precursor source comprising a dopant precursor, and a dopant precursor valve that is constructed and arranged to open and close the dopant precursor line. In such embodiments, a deposition step as described herein can further comprise providing the dopant precursor via the dopant precursor line to the reaction chamber to expose the substrate to the dopant precursor. In some embodiments, providing the dopant precursor to the reaction chamber and providing the precursor to the reaction chamber occur simultaneously. In some embodiments, the dopant precursor comprises boron. In some embodiments, the dopant precursor comprises a boron hydride such as borane, diborane, pentaborane, and dodecaborane. In some embodiments, the dopant precursor comprises a pnictogen hydride such as PH₃ and AsH₃. For example, the dopant precursor can be provided to the reaction chamber at a flow rate of at least 50 sccm to at most 900 sccm, for example from at least 100 sccm and to at most 600 sccm.

In some embodiments, at least one of the precursors and the dopant precursor can be introduced into to the reaction chamber in pure or substantially pure form. Alternatively, at least one of the precursors and the dopant precursor can be introduced into the reaction chamber mixed with a carrier gas. Suitable carrier gasses include N₂, H₂, and noble gasses such as He, Ne, Ar, Kr, and Xe. In some embodiments, the carrier gas can be introduced into the reaction chamber at a flow rate of at least 2.5 slm to at most 30 slm, or from at least 5 slm to at most 10 slm.

In some embodiments, the first surface comprises a monocrystalline semiconductor.

In some embodiments, the monocrystalline semiconductor comprises silicon. In some embodiments, the monocrystalline semiconductor comprises a silicon-germanium alloy. In some embodiments, the monocrystalline semiconductor comprises germanium. In some embodiments, the monocrystalline semiconductor comprises a direct bandgap semiconductor. In some embodiments, the monocrystalline semiconductor comprises an indirect bandgap semiconductor. In some embodiments, the monocrystalline semiconductor comprises an oxide semiconductor. In some embodiments, the monocrystalline semiconductor comprises a nitride semiconductor. In some embodiments, the monocrystalline semiconductor comprises a selenide semiconductor. In some embodiments, the monocrystalline semiconductor comprises a telluride semiconductor. In some embodiments, the monocrystalline semiconductor comprises a III-V material such as gallium arsenide.

In some embodiments, the second surface comprises a dielectric.

In some embodiments, the dielectric comprises one or more of silicon oxide and silicon nitride. In some embodiments, the dielectric comprises a post transition metal oxide such as aluminum oxide. In some embodiments, the dielectric comprises a transition metal oxide such as hafnium oxide. In some embodiments, the dielectric comprises a rare earth metal oxide such as lanthanum oxide.

In an exemplary embodiment of a cyclical deposition process as described herein, the reaction chamber can be kept at a pressure between 5 and 80 Torr, for example at a pressure between 20 and 60 Torr.

In an exemplary embodiment of a cyclical deposition process as described herein, the substrate was kept at a temperature below 500° C., for example at a temperature below 450° C., for example at a temperature of about 400° C.

In an exemplary embodiment of a cyclical deposition process according to the present disclosure, phosphorous-doped silicon was epitaxially grown on a monocrystalline silicon first surface with respect to a silicon nitride second surface. Disilane was used as a silicon precursor, phosphine was used as a dopant precursor, and nitrogen was used as a carrier gas. The deposition angular frequency was 7.854 rad/s, and the etching angular frequency was 3.665 rad/s. This yielded a within-wafer thickness non-uniformity of 14%, a phosphorous content non-uniformity of 18%, a sheet resistance non-uniformity of 13%, and a resistivity non-uniformity of 4%. This is much improved uniformity compared to a process in which the deposition angular frequency was equal to the etching angular frequency, in which case thickness non-uniformity was 98%, phosphorous content non-uniformity was 122%, sheet resistance non-uniformity was 220%, and resistivity non-uniformity was 38%. Selectivity was the same for both processes.

“Selectivity” as used herein can be measured as follows:

$$Selectivity = 100 \% \times ( \frac{Thickness on second surface}{Thickness on first surface} ) .$$

“Uniformity” as used herein can be measured as follows:

$$Uniformity = 100 \% \times ( 1 - \frac{Range}{Mean} ) .$$

1. A material deposition apparatus comprising
a reaction chamber comprising a substrate support;
the substrate support being constructed and arranged for supporting a substrate;
a substrate moving robot, the substrate moving robot being constructed and arranged for positioning the substrate on the substrate support;
a rotary actuator that is constructed and arranged for rotating the substrate support;
a precursor line which is constructed and arranged for fluidly connecting a precursor source comprising a precursor to the reaction chamber;
a precursor valve which is constructed and arranged for opening and closing the precursor line;
an etchant line which is constructed and arranged for fluidly connecting an etchant source comprising an etchant to the reaction chamber;
an etchant valve which is constructed and arranged for opening and closing the etchant line; and
a sequence controller which is constructed and arranged for causing the material deposition apparatus to execute a cyclical deposition process, the cyclical deposition process comprising executing a plurality of cycles, ones from the plurality of cycles comprising a deposition step and an etching step,
wherein the deposition step comprises
providing precursor via the precursor line to the reaction chamber to expose the substrate to the precursor while rotating the substrate support at a deposition angular frequency by the rotary actuator,
wherein the etching step comprises
providing etchant via the etchant line to the reaction chamber to expose the substrate to the etchant while rotating the substrate support at an etching angular frequency by the rotary actuator, the etching angular frequency being different from the deposition angular frequency,
to selectively form a layer on the first surface vis-à-vis the second surface.

2. The material deposition apparatus according to claim 1, wherein the layer is epitaxially formed on the first surface.

3. The material deposition apparatus according to claim 1, wherein the first surface comprises a monocrystalline semiconductor.

4. The material deposition apparatus according to claim 3, wherein the monocrystalline semiconductor comprises silicon.

5. The material deposition apparatus according to claim 1, wherein the second surface comprises a dielectric.

6. The material deposition apparatus according to claim 5, wherein the dielectric comprises one or more of silicon oxide and silicon nitride.

7. The material deposition apparatus according to claim 1, wherein the precursor comprises a silicon precursor.

8. The material deposition apparatus according to claim 7, wherein the silicon precursor has a general formula of the form SiₙH₂ₙ₋₂₋ₘXₘ, with X being selected from Cl, Br, and I, with n being an integer from at least 1 to at most 6, and with m being an integer from at least 0 to at most 2n-2.

9. The material deposition apparatus according to claim 8, wherein the silicon precursor comprises disilane.

10. The material deposition apparatus according to claim 1 that further comprises a dopant precursor line which is constructed and arranged for fluidly connecting a dopant precursor source comprising a dopant precursor to the reaction chamber; and a dopant precursor valve which is constructed and arranged for opening and closing the dopant precursor line, wherein the deposition step further comprises providing the dopant precursor via the dopant precursor line to the reaction chamber to expose the substrate to the dopant precursor.

11. The material deposition apparatus according to claim 10, wherein providing the dopant precursor to the reaction chamber and providing the precursor to the reaction chamber occur simultaneously.

12. The material deposition apparatus according to claim 10, wherein the dopant precursor comprises a phosphorous precursor.

13. The material deposition apparatus according to claim 12, wherein the phosphorous precursor comprises phosphine.

14. The material deposition apparatus according to claim 1, wherein the rotary actuator includes at least one of a stepper motor and a servo motor.

15. A method of forming a layer on a substrate, the substrate comprising a first surface and a second surface, the method comprising
positioning the substrate on a substrate support; and
a cyclical deposition process, wherein the cyclical deposition process comprises executing a plurality of cycles, ones from the plurality of cycles comprising a deposition step and an etching step,
wherein the deposition step comprises exposing the substrate to a precursor while rotating the substrate at a deposition angular frequency by the substrate support, and
wherein the etching step comprises exposing the substrate to an etchant while rotating the substrate at an etching angular frequency by the substrate support, the etching angular frequency being different from the rotation angular frequency,
thereby selectively forming the layer on the first surface vis-à-vis the second surface.
